(19) United States
(12) Patent Application Publication
(10) Pub. No.: US 2022/0320152 A1
(43) Pub. Date: Oct. 6, 2022

(54) PHOTOCONDUCTIVE SEMICONDUCTOR SWITCH LATERALLY FABRICATED ALONGSIDE GaN ON Si FIELD-EFFECT TRANSISTORS

(71) Applicant: Raytheon Company, Waltham, MA (US)

(72) Inventors: Matthew DeJarld, Wakefield, MA (US); Jeffrey R. LaRoche, Lowell, MA (US); Clay T. Long, Medford, MA (US); Lovelace Soirez, Andover, MA (US)

(73) Assignee: Raytheon Company, Waltham, MA (US)

(21) Appl. No.: 17/220,656

(22) Filed: Apr. 1, 2021

(51) Int. Cl. H01L 27/144

(52) U.S. Cl. CPC H01L 27/144

(57) ABSTRACT

An integrated circuit structure comprising a substrate having an upper surface; a gallium nitride layer disposed on the upper surface of the substrate; and a photoconductive semiconductor switch laterally disposed alongside a transistor on the gallium nitride layer integrated into the integrated circuit structure.

### BACKGROUND

The present disclosure is directed to the improved gallium nitride (GaN) integrated circuit technology, particularly, a structure that includes both GaN photoconductive semiconductor switch (PCSS) and/or photoconductively switched transistor and GaN transistors and accompanying integrated circuit structures.

Currently on-chip GaN on Si High Electron Mobility Transistor (HEMT) switches and RF devices are controlled through electrical signals and are limited by the constraints of traditional semiconductor device design, and fabrication. For example, switching speed is limited to device geometry, and the on-off current ratio. Another example includes the breakdown voltage of the device, which is the maximum voltage the device can handle before catastrophic device failure. This voltage is determined by the breakdown of the HEMT semiconductor material and/or dielectric when electric field peak at the drain side, which is a function of the applied drain bias and gate to drain distance, exceed the breakdown fields of the materials. The maximum operating voltage of current state of the art GaN HEMT switches, operating is a safe operating region below the breakdown voltage, is approximately 650 V. Photoconductive Semiconductor Switches (PCSS) and photoconductively switched transistors are different devices that offer high voltage switching capabilities, ultra-fast switching speeds, or rapid energy pulses that are switched by light instead of by biases applied by metal gates. As such, they offer the potential for increased operating voltages relative to traditional GaN HEMI switches and RF devices.

Further, existing GaN PCSS structures are stand-alone devices, fabricated through nonplanar liftoff based processing, that are connected with transistors, integrated circuits (ICs), and light sources (e.g. lasers and light emitting diodes), as part of a larger module, either through wire bonding or circuit board design.

What is needed for maximum performance and functional density is compact integration photoconductive semiconductor switches and photoconductively switched transistors.

### SUMMARY

In accordance with the present disclosure, there is provided an integrated circuit structure comprising a substrate having an upper surface; a gallium nitride layer disposed on the upper surface of the substrate; and a photoconductive semiconductor switch laterally disposed alongside a transistor on the gallium nitride layer integrated into the integrated circuit structure.

A further embodiment of any of the foregoing embodiments may additionally and/or alternatively include the substrate comprises at least one of a silicon material and a silicon carbide material.

A further embodiment of any of the foregoing embodiments may additionally and/or alternatively include the substrate and the gallium nitride layer comprise a wafer.

A further embodiment of any of the foregoing embodiments may additionally and/or alternatively include the transistor comprises a field-effect transistor.

A further embodiment of any of the foregoing embodiments may additionally and/or alternatively include the photoconductive semiconductor switch comprises a first electrical contact and a second electrical contact disposed on the GaN layer.

A further embodiment of any of the foregoing embodiments may additionally and/or alternatively include the photoconductive semiconductor switch comprises an aluminum gallium nitride layer disposed on a gallium nitride on silicon wafer, the first electrical contact and the second electrical contact being laterally arranged off-mesa on the gallium nitride layer of the wafer.

A further embodiment of any of the foregoing embodiments may additionally and/or alternatively include the aluminum gallium nitride layer is configured off-mesa in the absence of a two dimensional electron gas interface.

A further embodiment of any of the foregoing embodiments may additionally and/or alternatively include the photoconductive semiconductor switch comprises an aluminum gallium nitride layer disposed on a gallium nitride on silicon wafer, the first electrical contact and the second electrical contact are on-mesa being disposed on the aluminum gallium nitride layer.

A further embodiment of any of the foregoing embodiments may additionally and/or alternatively include an AlGaN—GaN two dimensional electron gas interface is present.

A further embodiment of any of the foregoing embodiments may additionally and/or alternatively include the integrated circuit structure further comprises a transparent silicon dioxide dielectric insulation layer configured to insulate each of the first electrical contact and the second electrical contact of the photoconductive semiconductor switch and the transistor.

A further embodiment of any of the foregoing embodiments may additionally and/or alternatively include the integrated circuit structure further comprises a light source optically coupled to the photoconductive semiconductor switch.

A further embodiment of any of the foregoing embodiments may additionally and/or alternatively include the photoconductive semiconductor switch and the transistor are each configured to be utilized separately or interdependently.

A further embodiment of any of the foregoing embodiments may additionally and/or alternatively include the photoconductive semiconductor switch is homogeneously integrated with the transistor on a gallium nitride on silicon wafer and configured to control the transistor.

A further embodiment of any of the foregoing embodiments may additionally and/or alternatively include the photoconductive semiconductor switch is homogeneously integrated with the transistor in a gallium nitride on silicon wafer and configured to be controlled by the transistor.

A further embodiment of any of the foregoing embodiments may additionally and/or alternatively include a dielectric and an interlayer are transparent to a light source utilized to trigger the photoconductive semiconductor switch.

Other details of the GaN on Si heterogeneous technology are set forth in the following detailed description and the accompanying drawings wherein like reference numerals depict like elements.

### BRIEF DESCRIPTION OF THE DRAWINGS

FIG. 1 is a cross-sectional schematic diagram of an exemplary laterally integrated circuit structure.

FIG. 2 is a cross-sectional schematic diagram of an exemplary GaN PCSS.

FIG. 3 is a cross-sectional schematic diagram of an exemplary GaN PCSS.

### DETAILED DESCRIPTION

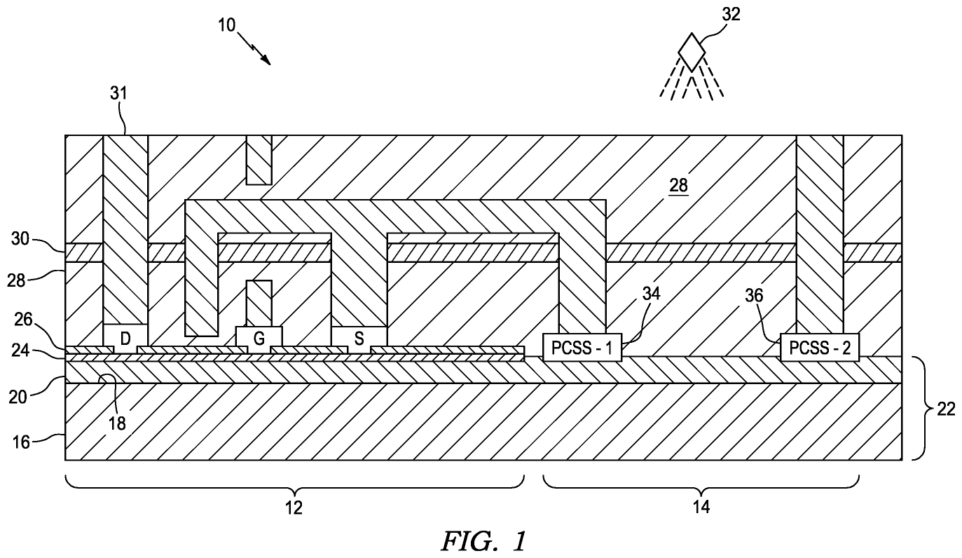

Referring to FIG. 1, there is illustrated a laterally integrated circuit structure 10. The laterally integrated circuit structure 10 includes a transistor 12 electrically coupled with a PCSS 14 each laterally integrated and supported on a common substrate 16. The transistor 12 can be a FET, for example, GaN transistors, Si transistors and accompanying integrated circuit structures. The PCSS 14 can include a GaN PCSS. The substrate 16 can include a silicon (Si) or silicon carbide (SiC) material. The substrate 16 includes an upper surface 18.

A gallium nitride (GaN) layer is disposed on the upper surface 18 of the substrate 16 to form a GaN on Si wafer 22. The GaN layer 20 supports the transistor 12 and the PCSS 14 in tandem such that the transistor 12 and PCSS 14 are laterally integrated and incorporated in the same integrated circuit.

The FET 12 includes an aluminum gallium nitride (AlGaN) layer 24 disposed on the GaN layer 20. The FET 12 includes silicon nitride dielectric (SiN/dielectric) layer 26 disposed on the AlGaN layer 24 proximate each of the drain D, gate G and source S of the FET 12. A silicon dioxide dielectric (SiO₂/dielectric) layer 28 insulates the transistor 12 circuitry as well as an interlayer 30, here for example SiNx, and conductive interconnects 31 disposed within the silicon dioxide dielectric layer 28. The dielectrics 28, 26 and interlayer 30 can be transparent to a light source 32 utilized to trigger the PCSS 14 conduction path. In an exemplary embodiment, in the event of the dielectric or interlayer not being transparent, a window can be opened in the films to allow for light transmission.

The PCSS 14 can include a first electrical contact 34 (PCSS-1) and a second electrical contact 36 (PCSS-2) disposed on the GaN layer. In an exemplary embodiment, the silicon dioxide dielectric layer 28 insulates each of the first electrical contact 34 and second electrical contact 36 of the photoconductive semiconductor switch 14. In exemplary embodiments, the dielectric layer 28 can be silicon nitride, or silicon dioxide material, and the like. In other exemplary embodiments, the first electrical contact 34 and second electrical contact 36 do not have dielectric insulation. A photoconductive semiconductor switch 14 is a region of semiconductor material (such as GaN) that is normally very highly resistive, here for example unintentionally doped or doped with a deep level such as carbon or iron. This allows the material to block a substantial amount of voltage with very low leakage. However, when illuminated with a light source 32 that has an energy above or near the band gap energy, a plethora of excited carriers are generated. These excited carriers now form a low-resistance conduction path used for switching. The PCSS 14 offers high voltage switching capabilities, ultra-fast switching speeds, or rapid energy pulses. An input voltage to the transistor 12 can be controlled by the on-off state of the PCSS 14 or the other way around.

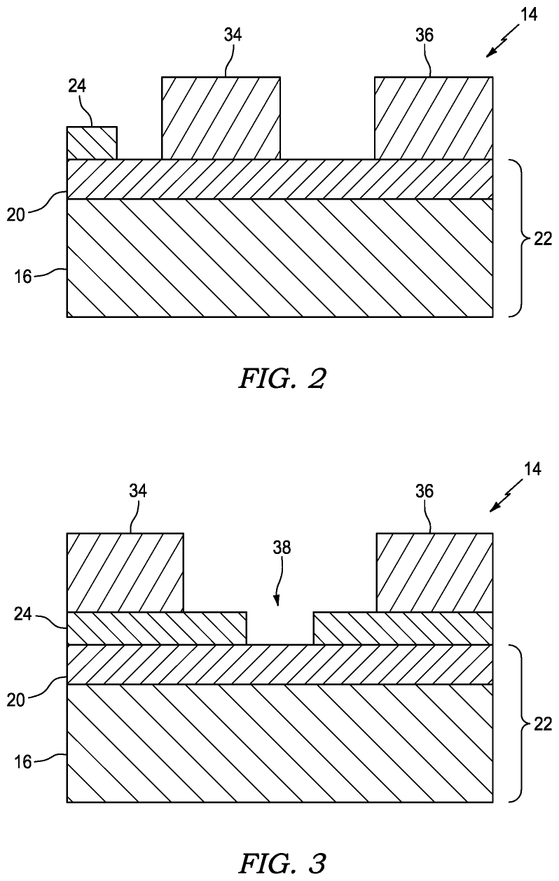

Referring also to FIG. 2, and FIG. 3, the GaN PCSS 14 can be fabricated in a variety of ways on the wafer 22.

As shown in FIG. 2, in an exemplary embodiment, the PCSS 14 can include the substrate 16 with the GaN layer 20 disposed on the substrate 16 that comprises the wafer 22. The AlGaN layer 24 can be configured off-mesa in the absence of a 2 dimensional electron gas (2DEG) interface. The first electrical contact 34 and second electrical contact 36 are laterally arranged off-mesa on the GaN layer 20 of the wafer 22.

As shown in FIG. 3, in an exemplary embodiment, the PCSS 14 can include the substrate 16 with the GaN layer 20 disposed on the substrate 16 that comprises the wafer 22. The first electrical contact 34 and the second electrical contact 36 are on-mesa, being disposed on the AlGaN layer 24, such that the AlGaN—GaN two dimensional interface (2DEG interface) is present. The AlGaN layer 24 can be etched to form a GaN window 38 in the 2DEG layer 24. The window 38 can have a variable width dimension that can influence the resistance of the junction in the PCSS 14.

A technical advantage of the disclosure includes integration of optically gated switches directly with the GaN on Si process flow to enable intrinsic high voltage capabilities and rapid response times of optically gated switches.

Another technical advantage of the disclosure includes a structure that includes a single chip/wafer that contains both GaN on Si transistor devices and GaN PCSS devices wherein the final device has the functions of GaN transistors, Si transistors, and GaN PCSS, utilized separately or interpedently.

Another technical advantage of the disclosure includes a PCSS device that controls, or is controlled by, a GaN plus Si device homogenously integrated in the same wafer.

Another technical advantage of the disclosure includes a structure that has multiple options for photoconductive materials, such as, an AlGaN/GaN 2DEG connected by a narrow region of photosensitive AlGaN/GaN material.

Another technical advantage of the disclosure includes fabricating the GaN PCSS can be layer-subtraction based, utilizing techniques traditional to Si foundries.

Another technical advantage of the disclosure includes both GaN PCSS and GaN/Si transistors are fabricated at the same time using the same processing steps.

Another technical advantage of the disclosure includes adding PCSS to a GaN on a Si device which is a nontrivial addition, as it utilizes layers and structure that would not be used in a standalone GaN on Si or standalone PCSS device.

Another technical advantage of the disclosure includes the 2DEG layer must be completely recessed through, unlike in GaN on Si devices.

Another technical advantage of the disclosure includes the substrate of an AlGaN/GaN high electron mobility transistor (HEMPT) epi being used, as opposed to a bulk substrate optimized for photosensitivity, unlike typical PCSS devices.

There has been provided a GaN on Si heterogeneous technology. While the GaN on Si heterogeneous technology has been described in the context of specific embodiments thereof, other unforeseen alternatives, modifications, and variations may become apparent to those skilled in the art having read the foregoing description. Accordingly, it is intended to embrace those alternatives, modifications, and variations which fall within the broad scope of the appended claims.

What is claimed is:

1. An integrated circuit structure comprising:
a substrate having an upper surface;
a gallium nitride layer disposed on said upper surface of the substrate; and
a photoconductive semiconductor switch laterally disposed alongside a transistor on said gallium nitride layer integrated into the integrated circuit structure.

2. The integrated circuit structure according to claim 1, wherein said substrate comprises at least one of a silicon material and a silicon carbide material.

3. The integrated circuit structure according to claim 1, wherein said substrate and said gallium nitride layer comprise a wafer.

4. The integrated circuit structure according to claim 1, wherein said transistor comprises a field-effect transistor.

5. The integrated circuit structure according to claim 1, wherein said photoconductive semiconductor switch comprises a first electrical contact and a second electrical contact disposed on the GaN layer.

6. The integrated circuit structure according to claim 5, wherein said photoconductive semiconductor switch comprises an aluminum gallium nitride layer disposed on a gallium nitride on silicon wafer, said first electrical contact and said second electrical contact being laterally arranged off-mesa on the gallium nitride layer of the wafer.

7. The integrated circuit structure according to claim 6, wherein said aluminum gallium nitride layer is configured off-mesa in the absence of a two dimensional electron gas interface.

8. The integrated circuit structure according to claim 5, wherein said photoconductive semiconductor switch comprises an aluminum gallium nitride layer disposed on a gallium nitride on silicon wafer, the first electrical contact and the second electrical contact are on-mesa being disposed on the aluminum gallium nitride layer.

9. The integrated circuit structure according to claim 8, wherein an AlGaN—GaN two dimensional electron gas interface is present.

10. The integrated circuit structure according to claim 1 further comprising:
a transparent silicon dioxide dielectric insulation layer configured to insulate each of the first electrical contact and the second electrical contact of the photoconductive semiconductor switch and the transistor.

11. The integrated circuit structure according to claim 1 further comprising:
a light source optically coupled to said photoconductive semiconductor switch.

12. The integrated circuit structure according to claim 1, wherein said photoconductive semiconductor switch and said transistor are each configured to be utilized separately or interdependently.

13. The integrated circuit structure according to claim 1, wherein said photoconductive semiconductor switch is homogeneously integrated with said transistor on a gallium nitride on silicon wafer and configured to control said transistor.

14. The integrated circuit structure according to claim 1, wherein said photoconductive semiconductor switch is homogeneously integrated with said transistor in a gallium nitride on silicon wafer and configured to be controlled by said transistor.

15. The integrated circuit structure according to claim 1, wherein a dielectric and an interlayer are transparent to a light source utilized to trigger the photoconductive semiconductor switch.
